(19) United States
(12) Patent Application Publication
(10) Pub. No.: US 2008/0315436 A1
(43) Pub. Date: Dec. 25, 2008

(54) SEMICONDUCTOR WAFER THAT SUPPORTS MULTIPLE PACKAGING TECHNIQUES

(75) Inventors: Stephen Mueller, Foothill Ranch, CA (US); Xuguang (Gary) Zhang, Aliso Viejo, CA (US); Matthew V. Kaufmann, Morgan Hill, CA (US)

Correspondence Address: FIALA & WEAVER, P.L.L.C.;C/O INTELLEVATE, P.O. BOX 52050, MINNEAPOLLS, MN, 55402, US

(73) Assignee: BROADCOM CORPORATION, Irvine, CA (US)

(21) Appl. No.: 11/766,000

(22) Filed: Jun. 20, 2007

(51) Int. Cl. H01L 23/48; H01L 21/768

(52) U.S. Cl. 257/778; 438/108; 257/E23.141; 257/E21.59

(57) ABSTRACT

Methods, systems, and apparatuses for semiconductor wafers and integrated circuit chip packaging techniques are provided. A wafer is fabricated that supports multiple different packaging techniques. The wafer is formed to have a plurality of integrated circuit regions. A first plurality of terminals is formed on a surface of the wafer in a central region of each integrated circuit region. A second plurality of terminals is formed on the surface of the wafer in a peripheral region of each integrated circuit region. For each integrated circuit region, each terminal of the second plurality of terminals is electrically coupled through the wafer to at least one terminal of the first plurality of terminals. The integrated circuit regions can be separated into chips that can be packaged in multiple ways. In an aspect, a wafer may be fabricated that supports wire-bond packaging or wafer level ball grid array (WLBGA) packaging for a common chip/die configuration of the wafer.

### BACKGROUND OF THE INVENTION

1. Field of the Invention

The present invention relates to semiconductor wafers, and more particularly, to wafer fabrication and packaging of integrated circuits of wafers.

2. Background Art

Integrated circuit (IC) chips or dies from semiconductor wafers are typically interfaced with other circuits using a package that can be attached to a printed circuit board (PCB). One such type of IC die package is a ball grid array (BGA) package. BGA packages provide for smaller footprints than many other package solutions available today. A BGA package has an array of solder ball pads located on a bottom external surface of a package substrate. Solder balls are attached to the solder ball pads. The solder balls are reflowed to attach the package to the PCB.

BGA packages are available in a variety of types. An example type of BGA package is a fine pitch BGA (FPBGA or FBGA) package. In a FBGA package, a chip is mounted to a substrate by a die attach material. Wirebonds electrically connect signals of the die to conductive features on the substrate. A mold compound encapsulates the die, wirebonds, and the entire top surface of the substrate. Solder balls of a FBGA package are smaller than solder balls of other BGA package types, such as plastic BGA (PBGA) packages, and a smaller ball pitch is used to space the solder balls.

Another type of BGA package is a wafer-level BGA (WLBGA) package. Wafer-level BGA packages have several names in industry, including wafer level chip scale packages (WLCSP), among others. In a wafer-level BGA package, the solder balls are mounted directly to the IC chip when the IC chip has not yet been singulated from its fabrication wafer. Wafer-level BGA packages can therefore be made very small, with high pin out, relative to other IC package types including traditional BGA packages.

Millions of integrated circuit packages are needed each year to interface integrated circuit chips with devices. Thus, what are needed are improved chip fabrication and packaging techniques that can help meet the high quantity production needs for integrated circuit packages.

### BRIEF SUMMARY OF THE INVENTION

Methods, systems, and apparatuses for semiconductor wafers and for integrated circuit chip packaging techniques are provided. In an aspect of the present invention, a wafer is fabricated that supports multiple different packaging techniques. The wafer may be fabricated prior to deciding on a particular packaging technique for chips of the wafer. Chips of the wafer can be assembled into different types of integrated circuit packages without modifying the chip layout.

In an example, a wafer is formed to have a plurality of integrated circuit regions. A first plurality of terminals is formed on a surface of the wafer in a central region of each integrated circuit region. A second plurality of terminals is formed on the surface of the wafer in a peripheral region of each integrated circuit region. For each integrated circuit region, each terminal of the second plurality of terminals is electrically coupled through the wafer to at least one terminal of the first plurality of terminals. The integrated circuit regions can be separated into chips that can be packaged in multiple ways. In an aspect, a wafer may be fabricated that supports wire-bond packaging and flip chip packaging for chips/dies of the wafer.

These and other objects, advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIGS. 1 and 2 show views of an example integrated circuit chip fabricated according to an embodiment of the present invention.

FIG. 3 shows an example wafer fabrication process step, according to an embodiment of the present invention.

FIG. 4 shows a plan view of a wafer having a plurality of integrated circuit regions, according to an example embodiment of the present invention.

FIG. 5 shows a flowchart providing example steps for the example wafer fabrication process step of FIG. 3.

FIG. 6 shows an example integrated circuit region of the wafer of FIG. 4, according to an embodiment of the present invention.

FIG. 7 shows a flowchart providing example steps for packaging chips of a wafer, according to embodiment of the present invention.

FIG. 8 shows a flowchart providing steps for an example wafer-level BGA packaging process, according to an embodiment of the present invention.

FIG. 9 shows a cross-sectional view of an example wafer-level BGA package formed according to the flowchart of FIG. 8, according to an embodiment of the present invention.

FIG. 10 shows a flowchart providing example steps for forming a wire bonded integrated circuit package, according to an embodiment of the present invention.

FIG. 11 shows a cross-sectional view of an example wire bond BGA package formed according to the flowchart of FIG. 10, according to an embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

### Introduction

The present specification discloses one or more embodiments that incorporate the features of the invention. The disclosed embodiment(s) merely exemplify the invention. The scope of the invention is not limited to the disclosed embodiment(s). The invention is defined by the claims appended hereto.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

### Example Embodiments

The example embodiments described herein are provided for illustrative purposes, and are not limiting. The examples described herein may be adapted to various types of integrated circuit packages. Furthermore, additional structural and operational embodiments, including modifications/alterations, will become apparent to persons skilled in the relevant art(s) from the teachings herein.

According to embodiments of the present invention provide, a semiconductor wafer is fabricated that supports multiple different packaging techniques. For example, in an embodiment, a wafer is fabricated that supports wire-bond packaging, such as used for standard fine-pitch ball grid array (FBGA) packages, or wafer level ball grid array (WLBGA) packaging for chips/dies of the wafer.

Embodiments allow for flexibility in chip packaging processes. Conventionally, a wafer is fabricated after an order for packages is received because the chips must be physically formed specific to the particular package type. For example, chips targeted for wire bond packaging must have pads/terminals located at perimeter edges of an active surface of the chips. Chips targeted for flip chip packaging may have pads/terminals located in an array throughout their active surface. It is typically not economically feasible to pre-form a large number of wafers with chips dedicated to a particular packaging type, because many such pre-formed wafers may go unused if orders for them are not placed. Because of this, conventional packaging processes typically receive wafers fabricated after an order for packages is received. A time required to fabricate a wafer can be very long, including months or longer. Thus, the time to conventionally fill a package order can be long due to the wafer fabrication and chip packaging both occurring after the package order is received.

In contrast, in embodiments of the present invention, wafers are fabricated to include chips that are packaging process flexible, and thus the wafers can be pre-fabricated. When a chip package order is received, the pre-fabricated wafers can immediately be used by a packaging process to assemble the packages. Thus, the packages can be assembled and delivered sooner than in conventional packaging processes, avoiding the additional months conventionally needed to fabricate wafers after receiving an order.

In embodiments, wafers that can be used in different packaging schemes can be tracked with a single part number because they are identical, as compared to conventional wafers for different packaging schemes needing different part numbers because they are configured differently. Embodiments save manufacturing costs in requiring a single mask set for a wafer that can be used in different packaging processes, rather than multiple mask sets being needed for multiple conventional wafers for different packaging schemes.

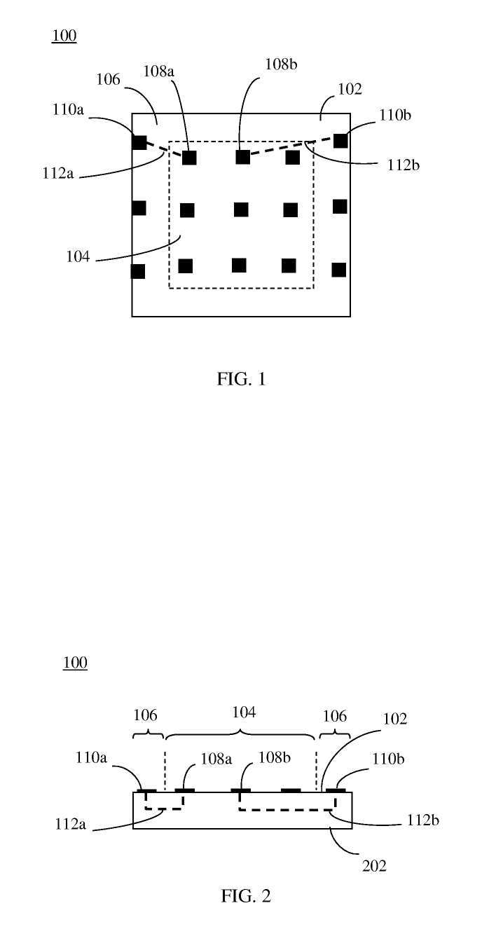

For example, FIGS. 1 and 2 show an example integrated circuit die or chip 100 separated from a wafer fabricated according to an embodiment of the present invention. FIG. 1 shows a plan view and FIG. 2 shows a cross-sectional view of chip 100. A first surface 102 (e.g., an active surface) of chip 100 is shown in FIG. 1. Chip 100 has a second surface 202 shown in FIG. 2 that is opposed to first surface 102. First surface 102 can be viewed as having two regions: a central region 104 and a peripheral region 106 located along a circumferential perimeter edge of first surface 102. Peripheral region 106 encircles central region 104 partially or entirely. In FIG. 1, central region 104 is shown as rectangular in shape, and peripheral region 106 is shown as frame-shaped. However, in other embodiments, central region 104 and peripheral region 106 can have other shapes.

As shown in FIGS. 1 and 2, central region 104 includes a first plurality of pads or terminals 108, including terminals 108a and 108b. Furthermore, peripheral region 106 includes a second plurality of pads or terminals 110, including terminals 110a and 110b. Terminals 108 and 110 are different types of terminals for chip 100. For example, in an embodiment, terminals 108 are flip chip pads/terminals, and terminals 110 are wire bond pads/terminals. Furthermore, as shown in FIGS. 1 and 2, terminals 108 of central region 104 are electrically coupled through chip 100 to corresponding terminals 110 of peripheral region 106 by electrical connections 112. For example, terminal 108a is electrically coupled through chip 100 to terminal 110a by a first electrical connection 112a, and terminal 108b is electrically coupled through chip 100 to terminal 110b by a second electrical connection 112b.

Electrical connections 112 are further coupled to electrical signals internal to chip 100. For example, electrical connection 112a may be coupled to an electrical signal of chip 100 that is desired to be accessible outside of chip 100, such as an I/O signal, a test signal, a power signal, a ground signal, etc. In this manner, the electrical signal coupled internal to chip 100 to electrical connection 112a is electrically coupled to both of terminals 108a and 110a. Thus, either of terminals 108a and 110a of chip 100 may be used to externally access the electrical signal. All signals of interest of chip 100 may be electrically coupled to pairs of terminals 108 and 110 by respective electrical connections 112, to be externally accessible to chip 100 in a redundant manner.

Terminals 108 and 110 and electrical connections 112 may be formed by standard wafer fabrication processes, such as by photolithographic techniques, etching techniques, thin film deposition techniques (e.g., sputtering, chemical vapor deposition (CVD), evaporative deposition, epitaxy, etc.), and/or other techniques. Electrical connections 112 may include one or more electrically conductive routes (e.g., metal traces, semiconductor material routes), electrically conductive vias, RDL (redistribution layer) layers, etc., formed on a single layer or multiple layers of the wafer from which chip 100 is derived. Electrical connections 112 are shown in FIGS. 1 and 2 as dotted lines to emphasize that they may be routed in any number of ways through chip 100 to electrically connect their respective terminals.

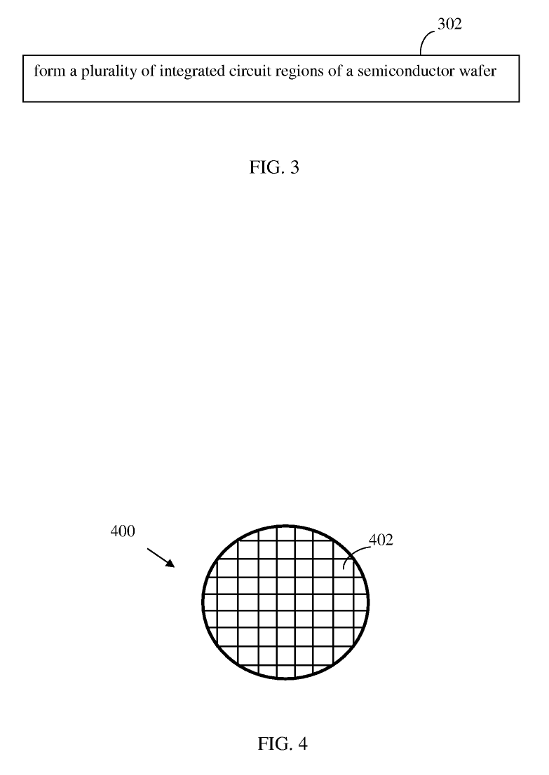

FIG. 3 shows an example wafer fabrication process step 302, according to an embodiment of the present invention. In step 302, a plurality of integrated circuit regions of a semiconductor wafer are formed. For example, FIG. 4 shows a plan view of a wafer 400. Wafer 400 may be silicon, gallium arsenide, or other wafer type. As shown in FIG. 4, wafer 400 has a surface 402 defined by a plurality of integrated circuit regions (shown as small rectangles in FIG. 4). Each integrated circuit region is configured to be packaged separately into either a wire bond integrated circuit package, such as a fine pitch BGA package, or a flip chip-type package, such as a wafer-level BGA package, according to embodiments of the present invention. The integrated circuit regions of wafer 400 may be formed according to conventional wafer fabrications processes, such as those mentioned elsewhere herein or otherwise known.

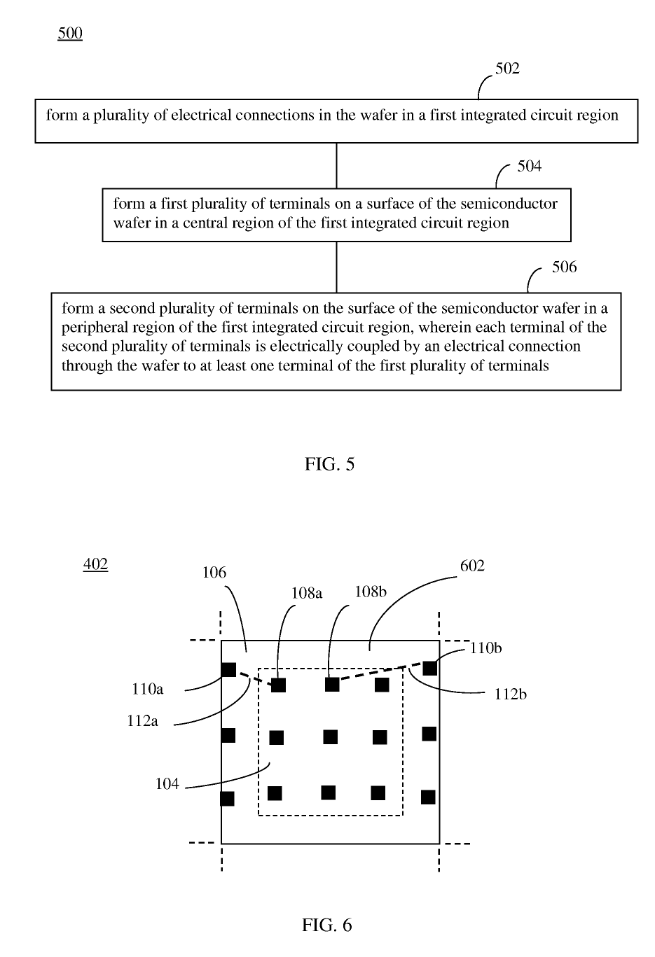

FIG. 5 shows a flowchart 500 providing example steps for step 302 of FIG. 3. The steps of flowchart 500 do not necessarily have to be performed in the order shown. Other structural and operational embodiments will be apparent to persons skilled in the relevant art(s) based on the discussion regarding flowchart 500. Flowchart 500 is described as follows.

Flowchart 500 begins with step 502. In step 502, a plurality of electrical connections is formed in the wafer in a first integrated circuit region. For example, FIG. 6 shows a plan view of a portion of surface 402 of wafer 400, including a first integrated circuit region 602 of the plurality of integrated circuit regions of wafer 400. Integrated circuit region 602 is eventually singulated from wafer 400 to form chip 100 shown in FIGS. 1 and 2. As shown in FIG. 6, electrical connections 112a and 112b are formed in first integrated circuit region 602 in wafer 400. Further electrical connections 112 not shown in FIG. 6 may additionally be formed in first integrated circuit region 602. Electrical connections 112 may be formed as described above or in other manner known to persons skilled in the relevant art(s) for forming electrical connections in an integrated circuit.

In step 504, a first plurality of terminals is formed on a surface of the semiconductor wafer in a central region of the first integrated circuit region. For example, as shown in FIG. 6, first plurality of terminals 108 is formed in central region 104 of first integrated circuit region 602. First plurality of terminals 108 may be formed according to any suitable fabrication techniques described elsewhere herein or otherwise known, including using metal plating or deposition techniques, etc. Any number of terminals 108 may be formed in central region 104, including 10 s and 100 s of terminals 108.

In step 506, a second plurality of terminals is formed on the surface of the semiconductor wafer in a peripheral region of the first integrated circuit region, wherein each terminal of the second plurality of terminals is electrically coupled by an electrical connection through the wafer to at least one terminal of the first plurality of terminals. For example, as shown in FIG. 6, second plurality of terminals 110 is formed in peripheral region 106 of first integrated circuit region 602. Second plurality of terminals 110 may be formed according to any suitable fabrication techniques described elsewhere herein or otherwise known, including using metal plating or deposition techniques, etc. Any number of terminals 110 may be formed in peripheral region 106, including 10 s and 100 s of terminals 110.

Furthermore, as shown in FIG. 6, terminals 108 are connected to corresponding terminals 110 by electrical connections 112. For example, terminal 108b is formed in step 504 at a first location of surface 402 in central region 104 at a first end of electrical connection 112b, and terminal 110b is formed in step 506 at a second location of surface 402 in peripheral region 106 at a second end of electrical connection 112b. In this manner, electrical connection 112b electrically connects terminal 108b to terminal 110b. Furthermore, electrical connection 112b is electrically coupled to an electrical signal of integrated circuit region 602 that is desired to be accessible outside of integrated circuit region 602, such as an I/O signal, a test signal, a power signal, a ground signal, etc. The electrical signal is accessible outside of integrated circuit region 602 through both of terminals 108b and 110b.

Note that in an embodiment, the forming of terminals according to steps 504 and 506 may be performed simultaneously. Note that flowchart 500 can be performed for all of the integrated circuit regions of wafer 400.

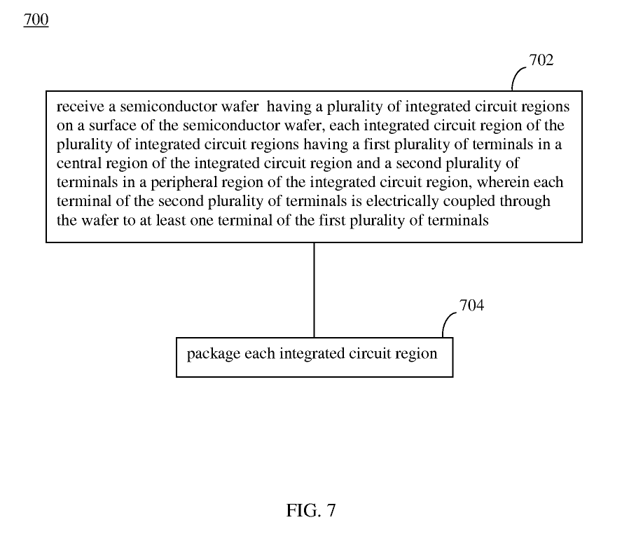

Subsequent to fabrication of wafer 400 as described above, flowchart 700 shown in FIG. 7 may be performed. Flowchart 700 shows example steps for packaging chips of a wafer, according to embodiment of the present invention. For example, flowchart 700 may be performed after an order for integrated circuit chip packages (e.g., FBGA or wafer level BGA packages) is received, before such an order is received, etc.

In step 702, a semiconductor wafer is received having a plurality of integrated circuit regions on a surface of the semiconductor wafer, each integrated circuit region of the plurality of integrated circuit regions having a first plurality of terminals in a central region of the integrated circuit region and a second plurality of terminals in a peripheral region of the integrated circuit region, wherein each terminal of the second plurality of terminals is electrically coupled through the wafer to at least one terminal of the first plurality of terminals. For example, wafer 400 may be received, having a plurality of integrated circuit regions formed as described above for integrated circuit region 602.

In step 704, each integrated circuit region is packaged. For example, each integrated circuit region 602 of wafer 400 may be packaged, according to one of the multiple package types for which the wafer is adapted. In an embodiment, performing step 704 includes electrically isolating terminals of one of the first plurality of terminals 108 or the second plurality of terminals 110 for each integrated circuit region, although this is not required. Examples of step 704 are described in detail as follows.

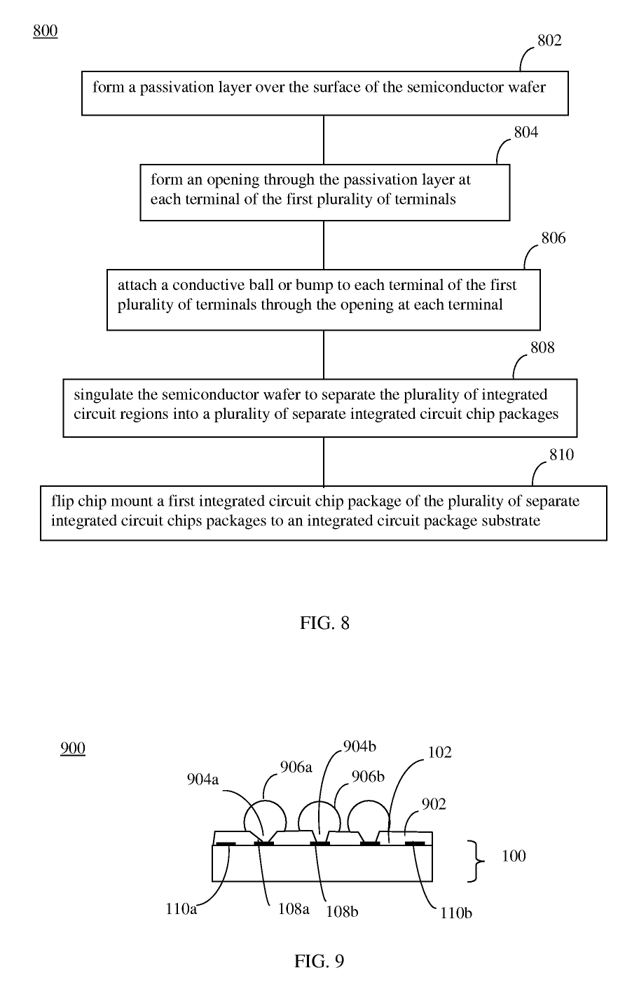

For example, in an embodiment, integrated circuit region 602 is configured to be packaged according to either of a wire bond packaging process or a wafer-level BGA packaging process. If a wafer-level BGA packaging process is selected (e.g., according to a customer request, etc.), flowchart 800 shown in FIG. 8 may be performed. Flowchart 800 shows an example wafer-level BGA packaging process, according to an embodiment of the present invention. The steps of flowchart 800 do not necessarily have to be performed in the order shown. Other structural and operational embodiments will be apparent to persons skilled in the relevant art(s) based on the discussion regarding flowchart 800. Flowchart 800 is described as follows.

Flowchart 800 begins with step 802. In step 802, a passivation layer is formed over the surface of the semiconductor wafer. For example, a passivation layer may be formed on surface 402 of wafer 400 shown in FIG. 4, including on integrated circuit region 602 shown in FIG. 6. FIG. 9 shows a cross-sectional view of an example wafer-level BGA package 900 formed according to flowchart 800. Wafer-level BGA package 900 includes chip 100 of FIGS. 1 and 2, and is formed by processing integrated circuit region 602 of FIG. 6 according to flowchart 800. As shown in FIG. 9, a passivation layer 902 is formed over surface 102 of chip 100. Passivation layer 902 may be an oxide layer, or layer of other suitable passivation material, for example,

In step 804, an opening is formed through the passivation layer at each terminal of the first plurality of terminals. For example, as shown in FIG. 9, an opening 904 is formed through passivation layer 902 at each of terminals 108 (of central region 104 shown in FIG. 6). For example, in FIG. 9, passivation layer 902 has an opening 904a that exposes terminal 108a and an opening 904b that exposes terminal 108b. Terminals 110a and 110b (in peripheral region 106 shown in FIG. 6) are covered by passivation layer 902 in step 802, and remain covered and isolated from external electrical contact. Openings 904 may be formed by any suitable process, including an etching process (e.g., chemical, photolithographic, laser, etc.), drilling, etc. Step 804 may be performed for each integrated circuit region of wafer 900.

In step 806, a conductive ball or bump is attached to each terminal of the first plurality of terminals through the opening at each terminal. As shown in FIG. 9, a conductive ball or bump 906 is attached to each terminal 108. For example, a conductive ball or bump 906a is attached to terminal 108a through opening 904a and a conductive ball or bump 906b is coupled to terminal 108b through opening 904b. Conductive balls or bumps 906 may be any electrically conductive ball/bump material, including a metal such as copper, aluminum, gold, silver, nickel, tin, a solder, other metal, or combination of metals/alloy. Step 806 may be performed for each integrated circuit region of wafer 900.

In step 808, the semiconductor wafer is singulated to separate the plurality of integrated circuit regions into a plurality of separate integrated circuit chip packages. For example, wafer 400 is singulated (e.g., diced, sawed, etc.) to separate integrated circuit regions 602 (e.g., shown in FIG. 6) into separate wafer-level packages, such as package 900 shown in FIG. 9, each having a respective chip 100. In this manner, a plurality of wafer-level BGA packages similar to package 900 can be formed from wafer 400.

In step 810, a first integrated circuit chip package of the plurality of separate integrated circuit chips packages is flip chip mounted to a substrate. Step 810 is optional. For example, step 810 may be performed to flip chip attach a wafer-level BGA package formed by step 808 to a subsequent substrate to form a larger package, such as a chip-scale package. For example, package 900 shown in FIG. 9 may be flip chip attached to a substrate by applying conductive balls or bumps 906 to a land pattern of the substrate, and reflowing conductive balls or bumps 906, or may be attached in another manner. Step 810 may be performed for each formed integrated circuit package formed by step 808, if desired.

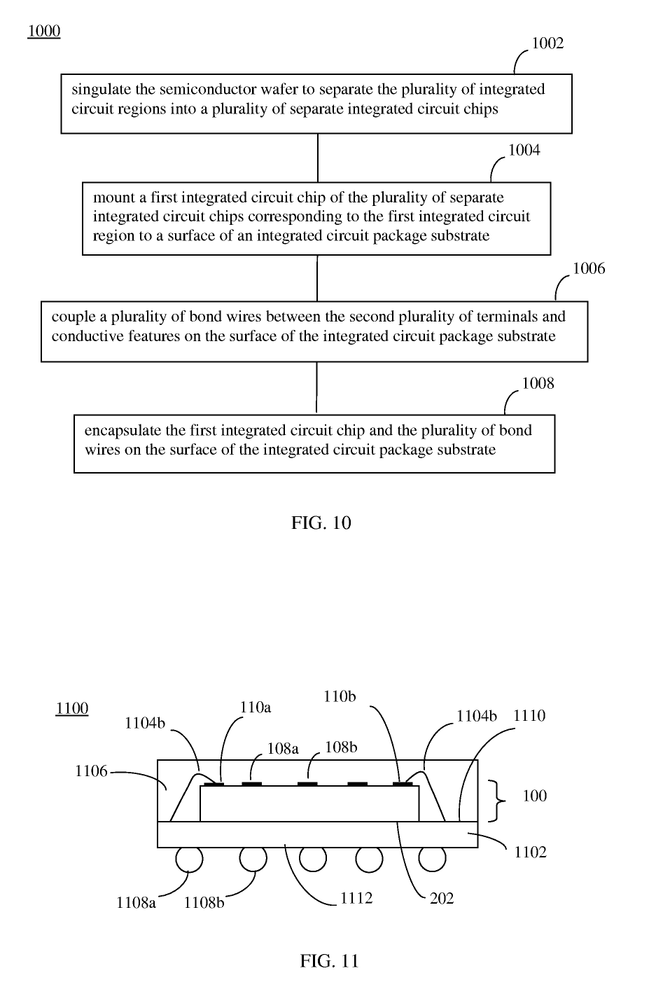

If a wire bonding type packaging process is selected prior to step 704 of flowchart 700 shown in FIG. 7 (e.g., alternatively to a wafer-level BGA packaging process), flowchart 1000 shown in FIG. 10 may be performed in step 704. Flowchart 1000 shows an example packaging process for a wire bonded integrated circuit package, according to an embodiment of the present invention. The steps of flowchart 1000 do not necessarily have to be performed in the order shown. Other structural and operational embodiments will be apparent to persons skilled in the relevant art(s) based on the discussion regarding flowchart 1000. Although described below in relation to an example FBGA package, flowchart 1000 is applicable to any type of integrated circuit package that incorporates wire bonding, including a leadframe-based integrated circuit package, a quad flat package (QFP), a quad flat package no leads (QFN) type package, and further types of wire bonded integrated circuit packages. Flowchart 1000 is described as follows.

Flowchart 1000 begins with step 1002. In step 1002, the semiconductor wafer is singulated to separate the plurality of integrated circuit regions into a plurality of separate integrated circuit chips. For example, wafer 400 is singulated (e.g., diced, sawed, etc.) to separate integrated circuit regions 602 (e.g., shown in FIG. 6) into separate chips, such as chip 100 shown in FIGS. 1 and 2. In this manner, a plurality of chips 100 can be formed from wafer 400.

Steps 1004-1008 described below may be performed on as many of chips 100 formed from wafer 400 in step 1002, as desired.

In step 1004, a first integrated circuit chip of the plurality of separate integrated circuit chips corresponding to the first integrated circuit region is mounted to a surface of an integrated circuit package substrate. For example, chip 100 of FIGS. 1 and 2 can be mounted to an integrated package substrate. FIG. 11 shows a cross-sectional view of an example FBGA package 1100 formed according to flowchart 1000. FBGA package 1100 includes chip 100 of FIGS. 1 and 2. As shown in FIG. 11, chip 100 is mounted to an integrated package substrate 1102, by attaching second surface 202 of chip 100 to a first surface 1110 of substrate 1102. Chip 100 may be mounted to substrate 1102 using an adhesive material (e.g., a chip attach material) (not shown in FIG. 11), as would be known to persons skilled in the relevant art(s).

In step 1006, a plurality of bond wires is coupled between the second plurality of terminals and conductive features on the surface of the integrated circuit package substrate. For example, as shown in FIG. 11, a plurality of bond wires 1104 are coupled between terminals 110 of chip 100 and conductive features, such as traces, bond fingers, etc. (not shown in FIG. 11), of first surface 1110 of substrate 1102. For example, a bond wire 1104a is connected between terminal 110a and first surface 1110 of substrate 1102, and a bond wire 1104b is connected between terminal 110b and first surface 1110 of substrate 1102. Bond wires 1104 may be wires formed of any suitable electrically conductive material, including a metal such as gold, silver, copper, aluminum, other metal, or combination of metals/alloy. Bond wires 1104 may be attached according to wire bonding techniques and mechanisms well known to persons skilled in the relevant art(s).

In step 1008, the first integrated circuit chip and the plurality of bond wires are encapsulated on the surface of the integrated circuit package substrate. For example, as shown in FIG. 11, an encapsulating material 1106 covers chip 100 and bond wires 1104 on first surface 1110 of substrate 1102. Encapsulating material 1106 protects chip 100 and bond wires 1104 from environmental hazards. Furthermore, as shown in FIG. 11, terminals 108a and 108b (in central region 104 shown in FIGS. 1 and 2) are covered by encapsulating material 1106, and thus are isolated from external electrical contact. Encapsulating material 1106 may be any suitable type of material, including an epoxy, a molding compound, etc. Encapsulating material 1106 may be applied in a variety of ways, including injecting into a mold applied to package substrate 1102, using a saw singulation technique, etc.

Note that FBGA package 1100 may be further processed, as desired. For example, as shown in FIG. 11, a plurality of solder balls 1108, including solder balls 1108a and 1108b, is attached to a second surface 1112 of substrate 1102. Substrate 1102 includes an array of solder balls pads on second surface 1112 to which solder balls 1108 are attached, that are electrically coupled through substrate 1102 to electrically conductive features of first surface 1110 of substrate 1102. Solder balls 1108 enable package 1100 to be mounted to another substrate, such as a circuit board, etc.

Other configurations for FBGA package 1100 are also within the scope of embodiments of the present invention. For example package 1100 in FIG. 11 is a die-up type BGA package. Alternatively, package 1100 may be configured as a die-down BGA package, where chip 100 is mounted to second surface 1112 of substrate 1102. Furthermore, package 1100 may include heat spreaders and/or heat sinks configured to spread heat within and/or outside package 1100. For example, in an embodiment, chip 100 may be mounted to a heat spreader/stiffener in package 1100. The heat spreader/stiffener may be attached to first surface 1110 of substrate 1102. The heat spreader/stiffener may have openings to allow bond wires 1104 to be coupled between terminals 110 of chip 100 and conductive features of substrate 1102.

Flowcharts 800 and 1000 respectively result in a wafer level BGA package (e.g., wafer level BGA package 900) and a wire bonded package (e.g., FBGA package 1100) from a common chip configuration that can be sold to customers, mounted in devices, or otherwise used as desired.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A method, comprising:
forming a plurality of integrated circuit regions of a semiconductor wafer, said forming including:
forming a first plurality of terminals on a surface of the semiconductor wafer in a central region of a first integrated circuit region of the plurality of integrated circuit regions, and
forming a second plurality of terminals on the surface of the semiconductor wafer in a peripheral region of the first integrated circuit region, wherein each terminal of the second plurality of terminals is electrically coupled through the wafer to at least one terminal of the first plurality of terminals.

2. The method of claim 1, further comprising:
forming a passivation layer over the surface of the semiconductor wafer;
forming an opening through the passivation layer at each terminal of the first plurality of terminals;
attaching a conductive ball or bump to each terminal of the first plurality of terminals through the opening at each terminal; and
singulating the semiconductor wafer to separate the plurality of integrated circuit regions into a plurality of separate integrated circuit chip packages.

3. The method of claim 2, further comprising:
flip chip mounting a first integrated circuit chip package of the plurality of separate integrated circuit chips corresponding to the first integrated circuit region to a substrate.

4. The method of claim 1, further comprising:
singulating the semiconductor wafer to separate the plurality of integrated circuit regions into a plurality of separate integrated circuit chips;
mounting a first integrated circuit chip of the plurality of separate integrated circuit chips corresponding to the first integrated circuit region to a surface of an integrated circuit package substrate;
coupling a plurality of bond wires between the second plurality of terminals and conductive features on the surface of the integrated circuit package substrate; and
encapsulating the first integrated circuit chip and the plurality of bond wires on the surface of the integrated circuit package substrate.

5. The method of claim 1, further comprising:
singulating the semiconductor wafer to separate the plurality of integrated circuit regions into a plurality of separate integrated circuit chips;
mounting a first integrated circuit chip of the plurality of separate integrated circuit chips corresponding to the first integrated circuit region to a surface of a heat spreader;
coupling a plurality of bond wires between the second plurality of terminals and conductive features on a surface of an integrated circuit package substrate through at least one opening through the heat spreader; and
encapsulating the first integrated circuit chip on the surface of the heat spreader.

6. A method for forming a plurality of integrated circuit packages, comprising:
receiving a semiconductor wafer having a plurality of integrated circuit regions on a surface of the semiconductor wafer, each integrated circuit region of the plurality of integrated circuit regions having a first plurality of terminals in a central region of the integrated circuit region and a second plurality of terminals in a peripheral region of the integrated circuit region, wherein each terminal of the second plurality of terminals is electrically coupled through the wafer to at least one terminal of the first plurality of terminals; and
packaging said each integrated circuit region, said packaging including electrically isolating terminals of one of the first plurality of terminals or the second plurality of terminals for each integrated circuit region.

7. The method of claim 6, wherein said packaging comprises:
forming a passivation layer over the surface of the semiconductor wafer;
forming an opening through the passivation layer at each terminal of the first plurality of terminals;
attaching a conductive ball or bump to each terminal of the first plurality of terminals through the opening at each terminal; and
singulating the semiconductor wafer to separate the plurality of integrated circuit regions into a plurality of separate integrated circuit chip packages.

8. The method of claim 7, wherein said packaging further comprises:
flip chip mounting each integrated circuit chip package to a corresponding substrate.

9. The method of claim 6, wherein said packaging comprises:
singulating the semiconductor wafer to separate the plurality of integrated circuit regions into a plurality of separate integrated circuit chips;
mounting each integrated circuit chip of the plurality of separate integrated circuit chips to a surface of a corresponding integrated circuit package substrate;
coupling a plurality of bond wires between the second plurality of terminals of each integrated circuit chip and a plurality conductive features on the surface of the corresponding integrated circuit package substrate; and
encapsulating each integrated circuit chip and the plurality of bond wires on the surface of the corresponding integrated circuit package substrate.

10. The method of claim 6, wherein said packaging comprises:
singulating the semiconductor wafer to separate the plurality of integrated circuit regions into a plurality of separate integrated circuit chips;
mounting each integrated circuit chip of the plurality of separate integrated circuit chips to a surface of a corresponding heat spreader;
coupling a plurality of bond wires between the second plurality of terminals of each integrated circuit chip and a plurality conductive features on a surface of a corresponding substrate through at least one opening through the corresponding heat spreader; and
encapsulating each integrated circuit chip on the surface of the corresponding heat spreader.

11. A semiconductor wafer, comprising:
a plurality of integrated circuit regions on a surface of the semiconductor wafer, each integrated circuit region of the plurality of integrated circuit regions having a first plurality of terminals in a central region of the integrated circuit region and a second plurality of terminals in a peripheral region of the integrated circuit region, wherein each terminal of the second plurality of terminals is electrically coupled through the wafer to at least one terminal of the first plurality of terminals.

12. The semiconductor wafer of claim 11, further comprising:
a passivation layer over the plurality of integrated circuit regions, wherein the passivation layer has an opening at each terminal of the first plurality of terminals through the passivation layer; and
a plurality of conductive balls or bumps, wherein each conductive ball or bump of the plurality of conductive balls or bumps is coupled to a corresponding terminal of the first plurality of terminals through a corresponding opening.

13. The semiconductor wafer of claim 11, wherein the second plurality of conductive terminals are wire bond terminals.

14. An integrated circuit chip package, comprising:
an integrated circuit chip having a first plurality of terminals and a second plurality of terminals on a surface;
wherein the first plurality of terminals are in a central region of the surface; and
wherein the second plurality of terminals are in a peripheral region of the surface, wherein each terminal of the second plurality of terminals is electrically coupled through the chip to at least one terminal of the first plurality of terminals.

15. The integrated circuit chip package of claim 14, further comprising:
a passivation layer over the surface of the integrated circuit chip having a plurality of openings through the passivation layer; and
a plurality of conductive balls or bumps attached to the first plurality of terminals through the plurality of openings.

16. The integrated circuit chip package of claim 15, further comprising:
an integrated circuit package substrate;
wherein the integrated circuit chip is flip chip mounted to the substrate.

17. The integrated circuit chip package of claim 14, further comprising:
an integrated circuit package substrate having a surface to which the integrated circuit chip is mounted;
a plurality of wire bonds coupled between the second plurality of terminals and conductive features on the surface of the integrated circuit package substrate; and
an encapsulating material that encapsulates the first integrated circuit chip, the plurality of bond wires, and the first plurality of terminals on the surface of the integrated circuit package substrate.

18. The integrated circuit chip package of claim 14, further comprising:
a heat spreader having a first surface to which the integrated circuit chip is mounted;
an integrated circuit package substrate attached to a second surface of the heat spreader;
a plurality of wire bonds coupled between the second plurality of terminals and conductive features on the surface of the integrated circuit package substrate through at least one opening through the heat spreader; and
an encapsulating material that encapsulates the first integrated circuit chip on the first surface of the heat spreader and encapsulates the plurality of bond wires.
